(19) United States
(12) Patent Application Publication
(10) Pub. No.: US 2026/0296261 A1
(43) Pub. Date: Oct. 1, 2026

(54) ELECTRONIC DEVICE AND METHOD WITH RECONFIGURATION OF BATTEY CONNECTION

(71) Applicant: SAMSUNG ELECTRONICS CO., LTD., Suwon-si (KR)

(72) Inventor: JINYONG JEON, Suwon-si (KR)

(73) Assignee: SAMSUNG ELECTRONICS CO., LTD., Suwon-si (KR)

(21) Appl. No.: 19/417,679

(22) Filed: Dec. 12, 2025

(30) Foreign Application Priority Data
Mar. 26, 2025 (KR) 10-2025-0038920

(51) Int. Cl. B60L 58/12; B60L 58/16; H01M 10/42; H01M 10/48; H02J 1/08; H02J 7/34

(52) U.S. Cl. CPC B60L 58/12; B60L 58/16; H01M 10/425; H01M 10/482; H02J 1/084; H02J 7/34; H01M 2220/20

(57) ABSTRACT

An electronic device and method of operating the electronic device are provided. The electronic device obtains sensing data of each of a plurality of batteries, determines state information of each of the batteries based on each of the obtained sensing data, obtains information for configuring a power source to supply power, selects at least one target battery from among the batteries based on each of the determined state information and the obtained information, and configures the power source based on the selected target battery.

### CROSS-REFERENCE TO RELATED APPLICATIONS

This application claims the benefit under 35 USC § 119 (a) of Korean Patent Application No. 10-2025-0038920, filed on Mar. 26, 2025, in the Korean Intellectual Property Office, the entire disclosure of which is incorporated herein by reference for all purposes.

### BACKGROUND

### 1. Field

The following description relates to an electronic device and method with reconfiguration of battery connection.

### 2. Description of Related Art

Electronic devices (e.g., electric vehicles, smartphones, and the like) typically include a battery pack composed of a plurality of battery cells. The battery cells within the battery pack may have similar quality and performance characteristics. Battery cells that demonstrate poor performance or substandard quality may be excluded during the manufacturing process and are not incorporated into the final battery pack.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, a method of operating an electronic device includes determining state information of each of a plurality of batteries based on sensing data associated with each of the plurality of batteries; obtaining information for configuring a power source to supply power; selecting at least one target battery from among the batteries based on each of the determined state information and the obtained information; and configuring the power source based on the selected target battery.

The information for configuring the power source may include any one or a combination of any two or more of a destination of a vehicle comprising the electronic device, driving environment information between a location of the vehicle and the destination, and state information of the vehicle.

The selecting of the target battery may include selecting the target battery based on a distance between a location of a vehicle comprising the electronic device and a destination of the vehicle, and a state of charge (SOC) of each of the batteries.

The obtaining of the information for configuring the power source may include obtaining driving environment information between a location of a vehicle comprising the electronic device and a destination of the vehicle, and the selecting of the target battery may include selecting the target battery based on the obtained driving environment information, an SOC of each of the batteries, and a state of health (SOH) of each of the batteries.

The selecting of the target battery may include selecting, as the target battery, a battery in a normal state in which a state of health (SOH) of the battery is greater than or equal to a first SOH value, when an operation mode of the electronic device is set to a life management mode for the batteries.

The selecting of the target battery may include selecting, as the target battery, a battery having a state of charge (SOC) greater than or equal to a first level, when weather information requires safe driving of a vehicle comprising the electronic device.

The selecting of the target battery may include selecting, as the target battery, a battery having a state of charge (SOC) greater than or equal to a second level, when a tire pressure value of a vehicle comprising the electronic device is less than or equal to a threshold value.

The method may further include converting a voltage of power output from the power source into a voltage required by a load.

The configuring of the power source may include, when multiple target batteries are selected, connecting the selected target batteries by controlling corresponding circuitry associated with each of the selected target batteries.

The corresponding circuitry of each of the selected target batteries may include either one or both of a switch and a transformer connected in parallel to each of the selected target batteries; and a switch connected in series to each of the selected target batteries.

In one general aspect, an electronic device includes a plurality of batteries; and
one or more processors configured to determine state information of each of the batteries based on sensing data associated with each of the batteries; obtain information for configuring a power source to supply power; select at least one target battery from among the batteries based on each of the determined state information and the obtained information; and configure the power source based on the selected target battery.

The one or more processors may be further configured to select the target battery based on a distance between a location of a vehicle comprising the electronic device and a destination of the vehicle, and a state of charge (SOC) of each of the batteries.

The one or more processors may be further configured to obtain driving environment information between a location of a vehicle comprising the electronic device and a destination of the vehicle, and select the target battery based on the obtained driving environment information, a state of charge (SOC) of each of the batteries, and a state of health (SOH) of each of the batteries.

The one or more processors may be further configured to select, as the target battery, a battery in a normal state in which a state of health (SOH) is greater than or equal to a first SOH value, when an operation mode of the electronic device is set to a life management mode for the batteries.

The one or more processors may be further configured to select, as the target battery, a battery having a state of charge (SOC) greater than or equal to a first level, when weather information requires safe driving of a vehicle comprising the electronic device.

The one or more processors may be further configured to select, as the target battery, a battery having a state of charge (SOC) greater than or equal to a second level, when a tire pressure value of a vehicle comprising the electronic device is less than or equal to a threshold value.

The electronic device may further include a converter configured to convert a voltage of power output from the power source into a voltage required by a load.

The one or more processors may be further configured to, when multiple target batteries are selected, connect the selected target batteries by controlling corresponding circuitry of each of the selected target batteries.

Other features and aspects will be apparent from the following detailed description, the drawings, and the claims.

### BRIEF DESCRIPTION OF THE DRAWINGS

FIG. 1 illustrates an example of an electronic device according to one or more embodiments.

FIGS. 2A and 2B illustrate examples of corresponding circuitry of a battery of an electronic device according to one or more embodiments.

FIGS. 3A and 3B illustrate other examples of corresponding circuitry of a battery of an electronic device according to one or more embodiments.

FIG. 4 illustrates an example of batteries and configuration circuitry of an electronic device according to one or more embodiments.

FIG. 5 illustrates another example of batteries and configuration circuitry of an electronic device according to one or more embodiments.

FIG. 6 illustrates an example method of obtaining information for configuring a power source by an electronic device according to one or more embodiments.

FIG. 7 illustrates an example selection of a target battery of an electronic device according to one or more embodiments.

FIG. 8 illustrates an example method of transferring power to a load from a configured power source of an electronic device according to one or more embodiments.

FIG. 9 illustrates another example method of transferring power to a load from a configured power source of an electronic device according to one or more embodiments.

FIG. 10 illustrates an example method of operating an electronic device according to one or more embodiments.

Throughout the drawings and the detailed description, unless otherwise described or provided, the same drawing reference numerals may be understood to refer to the same or like elements, features, and structures. The drawings may not be to scale, and the relative size, proportions, and depiction of elements in the drawings may be exaggerated for clarity, illustration, and convenience.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

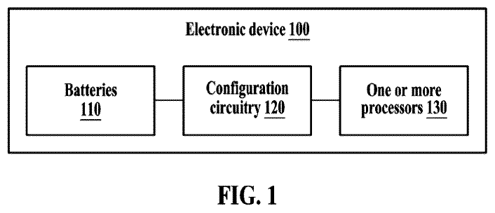

FIG. 1 illustrates an example electronic device according to one or more embodiments.

Referring to FIG. 1, an electronic device 100 may include batteries 110, configuration circuitry 120, and one or more processors (hereinafter referred to as “processor”) 130.

The electronic device 100 may correspond to, for example, an electric vehicle, a hybrid vehicle, an autonomous vehicle, an energy storage system, a robot, a drone, or a mobile terminal (e.g., a smartphone, a tablet personal computer (PC), or the like).

According to one or more embodiments, each of the batteries 110 may represent a battery cell. Without being limited thereto, each of the batteries 110 may represent a battery module or a battery pack. The battery module may include multiple battery cells connected in series and/or in parallel. The battery pack may include multiple battery modules connected in series and/or in parallel.

The batteries 110 (e.g., the battery cells, battery modules, or battery packs) may be connected in series.

The configuration circuitry 120 may be configured to form a power source by selectively connecting one or more of batteries 110 (e.g., at least one target battery, as described below). The configuration circuitry 120 may configure or reconfigure a connection among the batteries 110.

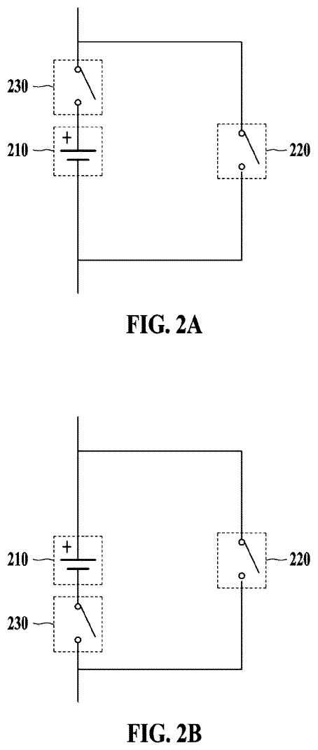

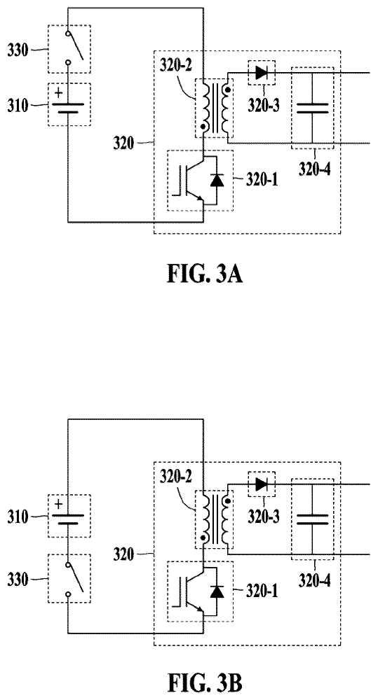

The configuration circuitry 120 may include individual circuitry corresponding to each of the batteries 110. For example, as described with reference to FIGS. 2A and 2B, the corresponding circuitry for each of the batteries 110 may include a switch connected to a corresponding battery in series and a switch connected to the corresponding battery in parallel. In another example, as illustrated in FIGS. 3A and 3B, the corresponding circuitry for each of the batteries 110 may include a switch and a transformer connected in series with the corresponding battery.

The processor 130 may obtain sensing data (e.g., current data, voltage data, and/or temperature data) of each of the batteries 110. For example, the processor 130 may receive voltage data (or a voltage value) of each of the batteries 110 from each of voltage sensors (not shown). The processor 130 may receive current data (or a current value) of each of the batteries 110 from each of current sensors (not shown). The processor 130 may receive temperature data (or a temperature value) of each of the batteries 110 from each of temperature sensors (not shown).

Based on the obtained sensing data, the processor 130 may determine state information of each of the batteries 110. The state information may include, but is not limited to, a state of charge (SOC), a state of health (SOH), a state of power (SOP), and/or a state of safety (SOS). The SOP may indicate available power of each of the batteries 110. The SOS may indicate safety risks such as internal short circuit, overcharging, or overdischarging of each of the batteries 110. In some examples, the processor 130 may input each obtained sensing data into a battery model (e.g., an electrochemical model or the like) to determine the state information of each of the batteries 110 through the battery model.

The processor 130 may obtain information for configuring a power source to supply power. Such information may include, for example, a destination of a vehicle incorporating the electronic device 100, driving environment information between a location of the vehicle and the destination (e.g., road information, weather information, etc.), and state information of the vehicle (e.g., a tire pressure state, etc.).

The processor 130 may select one or more target batteries from among the batteries 110 based on the state information of each of the batteries 110 and the information obtained for configuring the power source.

The processor 130 may configure the power source based on the selected target battery or batteries. For example, when a single target battery is selected, the processor 130 may control the configuration circuitry 120 to connect the single target battery to a load, bypassing the remaining batteries. When multiple target batteries are selected, the processor 130 may control the configuration circuitry 120 to connect the selected target batteries together. Under such control, the configuration circuitry 120 may connect the target batteries (e.g., in series), and the power source may supply power to the load using the selected target batteries. The remaining batteries that are not selected among the batteries 110 may be bypassed and excluded from supplying power to the load.

In conventional systems, battery packs are typically manufactured using battery cells with closely matched quality and performance, requiring screening processes to identify and select appropriate cells. These screening steps may result in additional cost and time to the manufacturing process. Furthermore, battery cells deemed to have poor quality or performance may be excluded from use, reducing manufacturing yield and increasing production costs. When the SOH of a battery pack in an electric vehicle falls below a certain threshold, the battery cells of the battery pack may be repurposed for use in other industries, which also often requires a screening process.

In contrast, according to one or more embodiments, the electronic device 100 may select one or more target batteries to configure the power source, allowing the batteries 110 to used even if there are differences in performance and quality among the batteries 110. This can reduce or eliminate the need for the aforementioned screening processes, thereby saving time and cost. In addition, the electronic device 100 may reconfigure the battery connections according to the purpose of use (e.g., cases requiring high current, low current, high voltage, and/or low voltage), thereby further enhancing the system's flexibility and efficiency.

FIGS. 2A and 2B illustrate respective examples of corresponding circuitry of a battery of an electronic device according to one or more embodiments.

Referring to FIGS. 2A and 2B, a battery 210, a switch 220, and a switch 230 are illustrated.

In the examples shown in FIGS. 2A and 2B, the corresponding circuitry of the battery 210 may include the switch 220 and the switch 230.

The switch 220 may be connected to the battery 210 in parallel, and the switch 230 may be connected to the battery 210 in series.

In FIG. 2A, the switch 230 may be connected to a cathode of the battery 210, and in FIG. 2B, the switch 230 may be connected to an anode of the battery 210.

When the processor 130 selects the battery 210 as a target battery, the processor 130 may transmit a turn-on signal to the switch 230 so that the switch 230 is in a turned-on state, and may not transmit the turn-on signal to the switch 220 so that the switch 220 is in a turned-off state. In this case, the switch 230 may be in the turned-on state and the switch 220 may be in the turned-off state.

When the processor 130 does not select the battery 210 as the target battery or determines that the battery 210 is in an abnormal state, the processor 130 may not transmit the turn-on signal to the switch 230 so that the switch 230 is in the turned-off state, and may transmit the turn-on signal to the switch 220 so that the switch 220 is in the turned-on state. In this case, the switch 230 may be in the turned-off state and the switch 220 may be in the turned-on state. According to one or more embodiments, when the processor 130 determines that the battery 210 is in an abnormal state, the processor 130 may bypass the battery 210 by transmitting the turn-on signal to the switch 220 without transmitting the turn-on signal to the switch 230. When the battery 210 is in an abnormal state, the battery 210 may not be selected as the target battery and may be excluded when configuring the power source.

FIGS. 3A and 3B illustrate additional examples of corresponding circuitry of a battery of an electronic device according to one or more embodiments.

Referring to FIGS. 3A and 3B, a battery 310, a first circuit 320, and a switch 330 are illustrated.

In the examples shown in FIGS. 3A and 3B, corresponding circuitry of the battery 310 may include the first circuit 320 and the switch 330.

In FIG. 3A, the switch 330 may be connected to a cathode of the battery 310, and in FIG. 3B, the switch 330 may be connected to an anode of the battery 310.

The first circuit 320 of FIGS. 3A and 3B may include a switch 320-1, a transformer 320-2, a diode 320-3, and a capacitor 320-4. The switch 320-1 may be implemented, for example, as a field effect transistor (FET), though other switch types may also be used.

The transformer 320-2 may include a first coil (or a first inductor) and a second coil (or a second inductor). In FIG. 3A, a first terminal of the first coil may be connected to the switch 330, and a second terminal of the first coil may be connected to the switch 320-1. In FIG. 3B, the switch 320-1 may be connected to the switch 330.

When the processor 130 selects the battery 310 as a target battery, the processor 130 may transmit the turn-on signal to the switch 330 so that the switch 330 is in the turned-on state, and may not transmit the turn-on signal to the switch 320-1 so that the switch 320-1 is in the turned-off state. In such cases, the switch 330 may be in the turned-on state and the switch 320-1 may be in the turned-off state.

When the processor 130 does not select the battery 310 as the target battery or determines that the battery 310 is in an abnormal state, the processor 130 may not transmit the turn-on signal to the switch 330 so that the switch 330 is in the turned-off state, and may transmit the turn-on signal to the switch 320-1 so that the switch 320-1 is in the turned-on state. In such cases, the switch 330 may be in the turned-off state and the switch 320-1 may be in the turned-on state. According to one or more embodiments, when the processor 130 determines that the battery 310 is in an abnormal state, the processor 130 may bypass the battery 310 by transmitting the turn-on signal to the switch 320-1 without transmitting the turn-on signal to the switch 330. When the battery 310 is in an abnormal state, the battery 310 may not be selected as the target battery and may be excluded when configuring the power source.

According to one or more embodiments, the processor 130 may perform a balancing operation when it determines that the batteries 110 are in an unbalanced state. For example, the processor 130 may identify that the battery 310 has the highest SOC among all of the batteries 110. The processor 130 may determine that the batteries 110 are in an unbalanced state when a difference value between a maximum SOC and a minimum SOC is greater than or equal to a predetermined threshold value. In this case, the processor 130 may generate a pulse width modulation (PWM) signal and apply the PWM signal to the switch 320-1. The switch 320-1 may be repeatedly turned on and off, according to the PWM signal. The PWM signal may be, for example, a signal having a duty ratio of less than 1 (or less than 100%). When the PWM signal is applied to the switch 320-1 (or when the second switch 320-1 is repeatedly turned off and on), current (or power) may be induced from the first coil of the transformer 320-2 to the second coil of the transformer 320-2. The current (or power) induced to the second coil may be smoothed by the diode 320-3 and the capacitor 320-4. The smoothed current (or power) may be used to charge other batteries in the system, thereby balancing the SOC across the batteries 110.

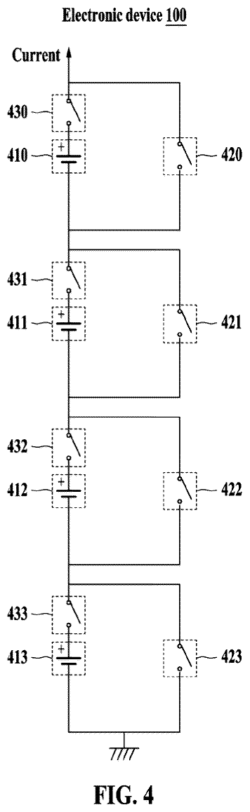

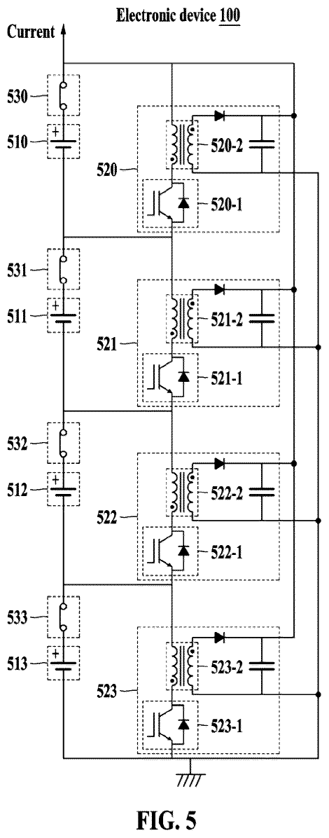

FIG. 4 illustrates an example of batteries and configuration circuitry of an electronic device according to one or more embodiments.

Referring to FIG. 4, the electronic device 100 may include batteries 410, 411, 412, and 413, and switches 420, 421, 422, 423, 430, 431, 432, and 433.

The switches 420 through 433 shown in FIG. 4 may be included in the configuration circuitry 120 of FIG. 1.

The batteries 410, 411, 412, and 413 may correspond to the example batteries 110 illustrated in FIG. 1. Each of the batteries 410, 411, 412, and 413 may represent a battery cell, a battery module, or a battery pack.

The processor 130 may select the battery 411 and the battery 413 as target batteries from among the batteries 410, 411, 412, and 413. For example, the selection may be based on the information for configuring the power source (e.g., one or more of a destination of a vehicle, driving environment information between a location of the vehicle and the destination, and state information of the vehicle) and state information of each of the batteries 410, 411, 412, and 413.

The processor 130 may control the configuration circuitry 120 to configure a power source to which the target batteries 411 and 413 are connected. For example, the processor 130 may transmit a turn-on signal to each of the switch 431 of the target battery 411 and the switch 433 of the target battery 413, and may not transmit the turn-on signal to each of the switch 421 of the target battery 411 and the switch 423 of the target battery 413. As a result, the switch 431 and the switch 433 may be in the turned-on state and the switch 421 and the switch 423 may be in the turned-off state. The processor 130 may not transmit the turn-on signal to each of the switch 430 of the battery 410 and the switch 432 of the battery 412, and may transmit the turn-on signal to each of the switch 420 of the battery 410 and the switch 422 of the battery 412. Consequently, the switch 430 and the switch 432 may be in the turned-off state and the switch 420 and the switch 422 may be in the turned-on state.

The target batteries 411 and 413 may be connected in series by the configuration circuitry 120 under the control of the processor 130. The batteries 410 and 412 may be bypassed by the configuration circuitry 120. The series-connected target batteries 411 and 413 (i.e., the power sources) may output current to a load.

FIG. 5 illustrates another example of batteries and configuration circuitry of an electronic device according to one or more embodiments.

Referring to FIG. 5, the electronic device 100 may include batteries 510, 511, 512, and 513; first circuits 520, 521, 522, and 523; and switches 530, 531, 532, and 533.

The batteries 510 through 513 may correspond to the example batteries 110 of FIG. 1. Each battery may represent a battery cell, a battery module, or a battery pack.

The first circuits 520 through 523 and the switches 530 through 533 shown in FIG. 5 may be part of the configuration circuitry 120 of FIG. 1.

The first circuit 520 of the battery 510 may include a switch 520-1 and a transformer 520-2. The first circuit 521 of the battery 511 may include a switch 521-1 and a transformer 521-2. The first circuit 522 of the battery 512 may include a switch 522-1 and a transformer 522-2. The first circuit 523 of the battery 513 may include a switch 523-1 and a transformer 523-2.

The processor 130 may select the battery 510 and the battery 511 as target batteries from among the batteries 510 through 513. For example, the selection may be based on the information for configuring the power source and state information of the respective batteries.

The processor 130 may control the configuration circuitry 120 to configure the power source to which the target batteries 510 and 511 are connected. For example, the processor 130 may transmit the turn-on signal to each of the switch 530 of the target battery 510 and the switch 531 of the target battery 511, and may not transmit the turn-on signal to each of the switch 520-1 of the target battery 510 and the switch 521-1 of the target battery 511. As a result, the switch 530 and the switch 531 may be in the turned-on state and the switch 520-1 and the switch 521-1 may be in the turned-off state. The processor 130 may not transmit the turn-on signal to each of the switch 532 of the battery 512 and the switch 533 of the battery 513, and may transmit the turn-on signal to each of the switch 522-1 of the battery 512 and the switch 523-1 of the battery 513. Accordingly, the switch 532 and the switch 533 may be in the turned-off state and the switch 522-1 and the switch 523-1 may be in the turned-on state.

The target batteries 510 and 511 may be connected in series by the configuration circuitry 120 under the control of the processor 130. The batteries 512 and 513 may be bypassed by the configuration circuitry 120. The series-connected target batteries 510 and 511 (i.e., the power sources) may output current to the load.

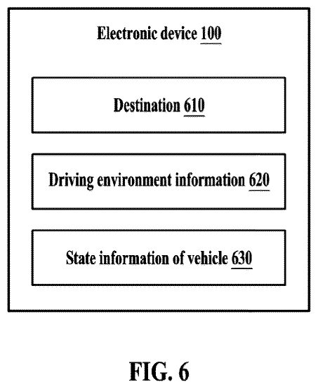

FIG. 6 illustrates an example of how an electronic device may obtain information for configuring a power source according to one or more embodiments.

Referring to FIG. 6, the electronic device 100 (e.g., the processor 130) may obtain information for configuring a power source, such as a destination 610, driving environment information 620, and/or state information 630 of a vehicle.

For example, the electronic device 100 (e.g., the processor 130) may receive the destination 610 of the vehicle from a user.

In another example, the electronic device 100 (e.g., the processor 130) may receive or obtain the driving environment information 620 corresponding to a route from a location of the vehicle to the destination 610. The driving environment information may include one or more of: a route from the location of the vehicle to the destination 610 of the vehicle, a distance the vehicle should drive along the route (hereinafter, referred to as a driving distance), road information regarding a road type (e.g., a highway or a city road) along the route, weather information, and surrounding vehicle information. For example, when the destination 610 of the vehicle is obtained, the electronic device 100 (e.g., the processor 130) may determine or retrieve the route from the location of the vehicle to the destination 610. The electronic device 100 (e.g., the processor 130) may receive or obtain the road information from a server. The road information may include, for example, but is not limited to, a first road type (e.g., a highway) or a second road type (e.g., a city road). The electronic device 100 (e.g., the processor 130) may receive or obtain the weather information from the server. The electronic device 100 (e.g., the processor 130) may obtain the surrounding vehicle information indicating how many vehicles are around the vehicle (e.g., in front of the vehicle, behind the vehicle, and/or beside the vehicle) through one or more cameras and/or sensors.

In another example, the electronic device 100 (e.g., the processor 130) may obtain the state information 630 of the vehicle. The state information 630 of the vehicle may include, for example, a tire pressure value of the vehicle and/or vehicle diagnostic information. For example, the electronic device 100 (e.g., the processor 130) may obtain the tire pressure value via an air pressure detection sensor. The electronic device 100 (e.g., the processor 130) may perform a vehicle diagnosis to obtain the vehicle diagnostic information (e.g., data indicating a faulty component among components of the vehicle, and the like) or may receive such diagnostic information from the server.

According to an example, the information for configuring the power source may include state information of a user (e.g., a driver's condition). For example, the state information of the user may include data indicating whether the driver is fit to operate the vehicle, is drowsy, or is distracted. Such information may be obtained using a driver monitoring system (DMS) installed in the vehicle.

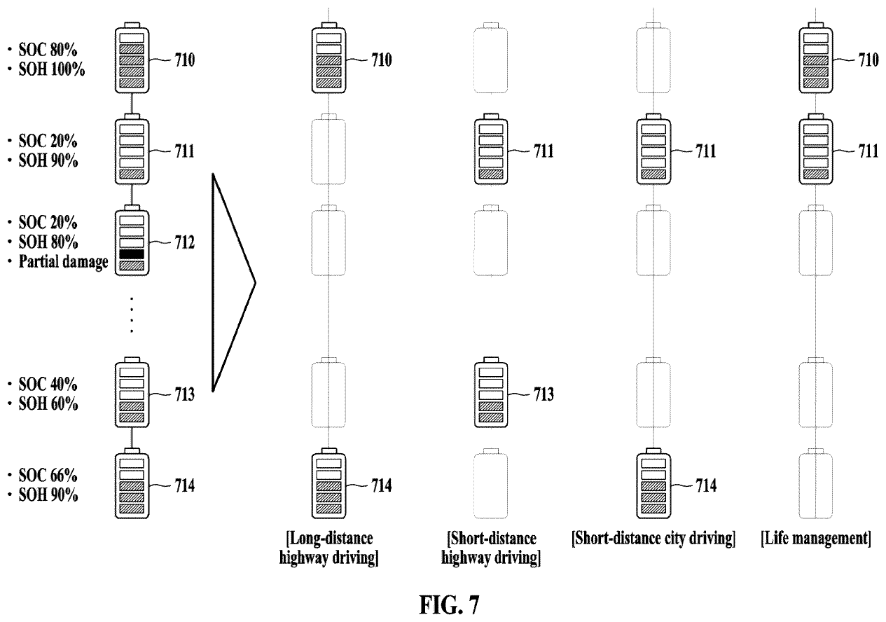

FIG. 7 illustrates an example of selection of a target battery of an electronic device according to one or more embodiments.

Referring to FIG. 7, batteries 710, 711, 712, 713, and 714 are illustrated.

The batteries 710 through 714 may correspond to the example batteries 110 shown in FIG. 1.

The electronic device 100 (e.g., the processor 130) may determine state information of each of the batteries 710 through 714 based on their respective sensing data. For example, the electronic device 100 (e.g., the processor 130) may determine the SOC and the SOH of each battery as shown in Table 1 below.

TABLE 1

| | |
|---|---|
| Battery 710 | SOC = 80%, SOH = 100% |
| Battery 711 | SOC = 20%, SOH = 90% |
| Battery 712 | SOC = 20%, SOH = 80% |
| Battery 713 | SOC = 40%, SOH = 60% |
| Battery 714 | SOC = 66%, SOH = 90% |

The SOC and SOH values in Table 1 above are provided merely as examples for convenience of description, and the SOC and SOH of each battery are not limited to the examples shown in Table 1 above.

As shown in Table 1 above, the performance and quality of the batteries 710 through 714 may differ from each other.

The electronic device 100 (e.g., the processor 130) may determine whether each battery is in a normal state or abnormal state using a battery model. For example, the electronic device 100 (e.g., the processor 130) may input sensing data of each battery to a battery model (e.g., an electrochemical model) and obtain information on the normal state of each battery from the battery model. In the example shown in FIG. 7, the electronic device 100 (e.g., the processor 130) may determine or estimate that the battery 712 is in an abnormal state using the battery model. The abnormal state of the battery 712 may include, for example, partial damage to the battery 712 (e.g., electrolyte loss, electrode damage, or separator damage). The electronic device 100 (e.g., the processor 130) may determine that each of the remaining batteries 710, 711, 713, and 714 is in the normal state. The abnormal state of the battery 712 is not limited to the above-described partial damage, and if the battery 712 has an internal short circuit greater than or equal to a predetermined level, the electronic device 100 (e.g., the processor 130) may determine or estimate that the battery 712 is in the abnormal state.

The electronic device 100 (e.g., the processor 130) may select a target battery from among the normal batteries (710, 711, 713, and 714), excluding the battery 712 due to its abnormal state, because the battery 712 may have partial damage. The electronic device 100 (e.g., the processor 130) may bypass the partially damaged battery 712.

According to one or more embodiments, the electronic device 100 (e.g., the processor 130) may select one or more target batteries based on driving environment information (e.g., a driving distance and/or road type) and state information of each battery.

For example, the electronic device 100 (e.g., the processor 130) may determine the driving distance as a long distance (or determine the driving to be performed by the vehicle as long-distance driving) when the driving distance is greater than or equal to a first distance value. The electronic device 100 (e.g., the processor 130) may determine the driving distance as a medium distance (or determine the driving to be performed by the vehicle as medium-distance driving) when the driving distance is less than the first distance value and greater than or equal to a second distance value. The electronic device 100 (e.g., the processor 130) may determine the driving distance as a short distance (or determine the driving to be performed by the vehicle as short-distance driving) when the driving distance is less than the second distance value. The electronic device 100 (e.g., the processor 130) may determine whether the type of road on which the vehicle is to travel is the first road type (e.g., a highway) or the second road type (e.g., a city road) based on the road information. The electronic device 100 (e.g., the processor 130) may determine whether the driving to be performed by the vehicle is highway driving or city driving based on the road information.

The electronic device 100 (e.g., the processor 130) may determine that the driving to be performed by the vehicle (or the driving of the vehicle) is long-distance driving and highway driving. In other words, the driving distance of the vehicle may be greater than or equal to the first distance value and the road information may correspond to a highway. In this case, the electronic device 100 (e.g., the processor 130) may select a battery with an SOC value that is greater than or equal to the first SOC value as the target battery. As shown in the example in FIG. 7, the SOC of the battery 710 and the SOC of the battery 714 may each be greater than or equal to the first SOC value, and thus, the electronic device 100 (e.g., the processor 130) may select the batteries 710 and 714 as the target batteries.

The electronic device 100 (e.g., the processor 130) may determine that the driving to be performed by the vehicle (or the driving of the vehicle) is short-distance driving and highway driving. In other words, the driving distance of the vehicle may be less than the second distance value and the road information may correspond to a highway. In this case, the electronic device 100 (e.g., the processor 130) may select a battery with an SOC value that is less than the first SOC value as the target battery. As shown in the example in FIG. 7, the SOC of the battery 711 and the SOC of the battery 713 may each be less than the second SOC value, and thus, the electronic device 100 (e.g., the processor 130) may select the batteries 711 and 713 as the target batteries.

The first SOC value described above may be greater than the second SOC value. Without being limited thereto, the first SOC value and the second SOC value may be equal to each other. These threshold values (e.g., the first and second SOC values) may each be determined based on an average SOC value of the normal batteries (e.g., batteries 710, 711, 713, and 714).

The electronic device 100 (e.g., the processor 130) may determine that the driving to be performed by the vehicle is short-distance driving and city driving. In other words, the driving distance may be less than the second distance value and the road information may correspond to a road in the city. In this case, the electronic device 100 (e.g., the processor 130) may select the target batteries by considering the SOC and the SOH of each of the batteries 710, 711, 713, and 714. For example, the electronic device 100 (e.g., the processor 130) may calculate a score for each battery by applying a first weight to the SOC of each battery and a second weight to the SOH of each battery. The electronic device 100 (e.g., the processor 130) may select each of the top n batteries with high scores (or batteries with scores higher than or equal to a predetermined score) as a target battery. In the example shown in FIG. 7, the electronic device 100 (e.g., the processor 130) may select the batteries 711 and 714 as the target batteries since the respective scores of the batteries 711 and 714 may be high.

The electronic device 100 (e.g., the processor 130) may determine that the driving to be performed by the vehicle is medium-distance driving (or long-distance driving) and city driving. In this case, the electronic device 100 (e.g., the processor 130) may calculate the score of each battery by applying a third weight to the SOC of each battery and a fourth weight to the SOH of each battery, and may select each of the top n batteries with high scores as the target battery. Here, the third weight may be different from the first weight, and the fourth weight may be different from the second weight. For example, the third weight may be greater than the first weight, and the fourth weight may be less than or equal to the second weight.

When the driving to be performed by the vehicle is city driving, the electronic device 100 (e.g., the processor 130) may use the SOH as well as the SOC of each battery to select the target battery. In such cases, the electronic device 100 (e.g., the processor 130) may apply a greater weight to the SOC than the SOH when the driving to be performed by the vehicle is medium-distance driving (or long-distance driving), and may apply a greater weight to the SOH than the SOC when the driving to be performed by the vehicle is short-distance driving. According to the implementation, the electronic device 100 (e.g., the processor 130) may select a battery with an SOC value higher than or equal to a predetermined level and an SOH value lower than a predetermined level as the target battery when the driving to be performed by the vehicle is medium-distance driving (or long-distance driving) and city driving. The electronic device 100 (e.g., the processor 130) may select a battery with an SOC value lower than a predetermined level and an SOH value higher than or equal to a predetermined level as the target battery when the driving to be performed by the vehicle is short-distance driving and city driving.

According to one or more embodiments, during the driving of the vehicle, the driving of the vehicle may change from highway driving to city driving. For example, the vehicle may exit the highway and perform city driving. During the driving of the vehicle, the road type may change from the first road type to the second road type. When it is detected that the driving of the vehicle changes from highway driving to city driving (or when it is detected that the road type changes from highway to city road), the electronic device 100 (e.g., the processor 130) may select one or more target batteries from among the batteries 710, 711, 713, and 714. For example, when the driving of the vehicle corresponds to highway driving and long-distance driving, the electronic device 100 (e.g., the processor 130) may select the batteries 710 and 714 as the target batteries. The batteries 710 and 714 may configure a power source to supply power to the vehicle during the driving of the vehicle. When it is detected that the driving of the vehicle changes from highway driving to city driving, the electronic device 100 (e.g., the processor 130) may reselect one or more target batteries using the SOC and the SOH of each battery. In such cases, the batteries 711 and 714 may be selected as the target batteries. The electronic device 100 (e.g., the processor 130) may change the power source through the configuration circuitry 120 from the batteries 710 and 714 to the batteries 711 and 714 during a vehicle stop. The batteries 711 and 714 may configure a power source to supply power to the vehicle during the city driving of the vehicle.

According to one or more embodiments, the electronic device 100 (e.g., the processor 130) may set an operation mode of the electronic device 100 to a life management mode. For example, the electronic device 100 (e.g., the processor 130) may receive information indicating the electronic device 100 to operate in the life management mode from a user. In another example, the electronic device 100 (e.g., the processor 130) may set the operation mode of the electronic device 100 to the life management mode when a difference value between a maximum SOH and a minimum SOH is greater than or equal to a predetermined value. The life management mode may represent, for example, a mode for equalizing the SOH of each battery. When the operation mode of the electronic device 100 is set to the life management mode, the electronic device 100 (e.g., the processor 130) may select, as the target battery, a battery with an SOH value greater than or equal to a first SOH value (or an average SOH value) from among the batteries 710, 711, 713, and 714. In the example shown in FIG. 7, the respective SOH values of the batteries 710 and 711 may be greater than or equal to the first SOH value (or the average SOH value of the batteries 710, 711, 713, and 714). In this case, the electronic device 100 (e.g., the processor 130) may select the batteries 710 and 711 as the target batteries.

According to one or more embodiments, the electronic device 100 (e.g., the processor 130) may select one or more target batteries based on weather information and state information of each battery. For example, when the weather information corresponds to weather information that requires safe driving of a vehicle (e.g., rainy weather, snowy weather, foggy weather, or strong windy weather), the electronic device 100 (e.g., the processor 130) may select a battery with an SOC value higher than or equal to a first level as the target battery from among the batteries 710, 711, 713, and 714. Here, the first level may include, for example, but is not limited to, the first SOC value or the average SOC value. The first level may have a value different from the first SOC value or may be different from the average SOC value.

According to one or more embodiments, the electronic device 100 (e.g., the processor 130) may select one or more target batteries based on state information of the vehicle and state information of each battery. For example, when the tire pressure value of the vehicle is less than or equal to a threshold value, the electronic device 100 (e.g., the processor 130) may select a battery with an SOC value lower than or equal to a second level as the target battery from among the batteries 710, 711, 713, and 714. Here, the second level may include, for example, but is not limited to, the first SOC value or the average SOC value. The second level may have a value different from the first SOC value or may be different from the average SOC value. The second level may be different from the first level.

According to one or more embodiments, the electronic device 100 (e.g., the processor 130) may select one or more target batteries based on any one or any two or more combination of the driving distance of the vehicle, the road type on the route of the vehicle, the weather information, the state information of the vehicle, the state information of a driver, and the state information of each battery. For example, when it is determined that the driving distance of the vehicle is a long distance, the road type is a highway, the weather is rainy, and the driver is capable of driving normally, the electronic device 100 (e.g., the processor 130) may select each of the top n batteries with high SOC values as the target battery.

The description provided with reference to FIGS. 1 through 6 may apply to the operations of the electronic device of FIG. 7.

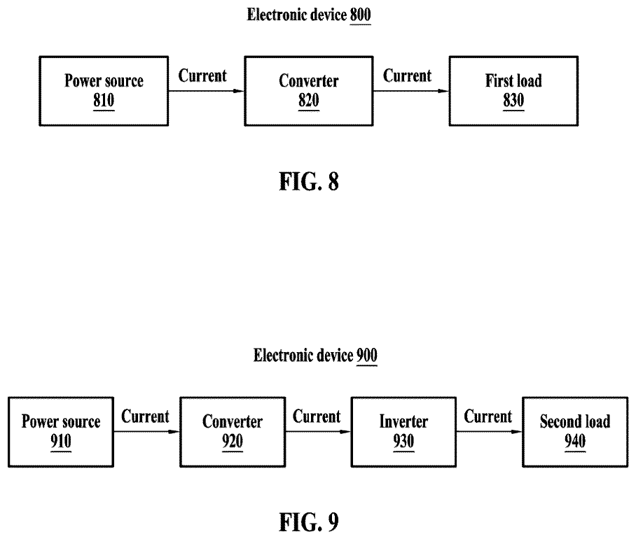

FIG. 8 illustrates an example in which power is transferred to a load from a configured power source of an electronic device according to one or more embodiments.

Referring to FIG. 8, an electronic device 800 (e.g., the electronic device 100) may include a power source 810, a converter 820, and a first load 830.

The power source 810 may include one or more target batteries (e.g., the one or more target batteries described with reference to FIG. 7). When the electronic device 800 selects a plurality of target batteries, the selected target batteries may be connected in series through the configuration circuitry 120. In this case, the power source 810 corresponds to target batteries connected in series. For example, when the driving of the vehicle corresponds to highway driving and long-distance driving, the electronic device 800 may select both the battery 710 and the battery 714 of FIG. 7 as the target batteries, and may configure the power source 810 by connecting the batteries 710 and 714 in series using the configuration circuitry 120. The batteries 711, 712, and 713 may be excluded from the power source 810 by being bypassed via the configuration circuitry 120.

The power source 810 may output a current (or power).

The converter 820 may convert a voltage of the input current (or power). For example, the converter 820 may convert the voltage (e.g., elevate the voltage) to match a voltage level required by the first load 830.

The first load 830 may include, but is not limited to, various electronic components (e.g., a display, illumination, camera, sensor, air conditioning system, and the like of a vehicle) within the electronic device 800 (e.g., a vehicle).

The description provided with reference to FIGS. 1 through 7 may also apply to the electronic device 800 of FIG. 8.

FIG. 9 illustrates another example in which power is transferred to a load from a configured power source of an electronic device according to one or more embodiments.

Referring to FIG. 9, an electronic device 900 (e.g., the electronic device 100) may include a power source 910, a converter 920, an inverter 930, and a second load 940.

The power source 910 may include one or more target batteries (e.g., the one or more target batteries described with reference to FIG. 7). When the electronic device 900 selects a plurality of target batteries, the target batteries may be connected in series, forming the power source 910.

The power source 910 may output a current (or power). The current output from the power source 910 may correspond to a direct current (DC).

The converter 920 may convert a voltage of the input current (or power). For example, the converter 920 may convert the voltage (e.g., elevate the voltage) to match a level required by the second load 940. The second load 940 may include, but is not limited to, a motor (e.g., an alternating current (AC) motor) of a vehicle.

The inverter 930 may convert the current output from the converter 920 into the AC (e.g., three-phase AC). The three-phase AC may be transferred to the second load 940.

The description provided with reference to FIGS. 1 through 8 may also apply to the electronic device 900 of FIG. 9.

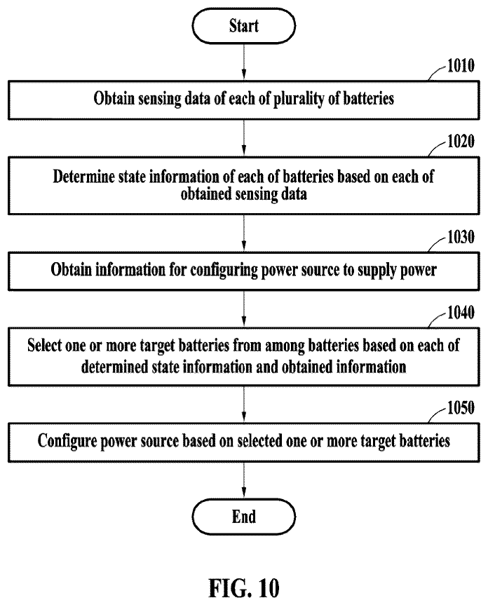

FIG. 10 illustrates an example method of operating an electronic device according to one or more embodiments.

Operations 1010 through 1050 of FIG. 10 may be performed by an electronic device (e.g., the electronic device 100, 800, or 900).

In operation 1010, the electronic device may obtain sensing data of each of a plurality of batteries.

In operation 1020, the electronic device may determine state information of each battery based on the respective sensing data.

In operation 1030, the electronic device may obtain information for configuring a power source for power supply.

In operation 1040, the electronic device may select one or more target batteries from among the batteries based on each of the determined state information and the obtained information.

For example, the electronic device (e.g., the processor 130) may select a target battery based on a distance between a location of a vehicle including the electronic device and a destination of the vehicle and an SOC of each battery.

In another example, the electronic device (e.g., the processor 130) may select a target battery based on driving environment information, an SOC of each battery, and an SOH of each battery.

In another example, the electronic device (e.g., the processor 130) may select, as the target battery, a battery in a normal state in which an SOH is greater than or equal to a first SOH value from among the batteries, when an operation mode of the electronic device is set to a life management mode for the batteries.

In another example, the electronic device (e.g., the processor 130) may select, as the target battery, a battery in which an SOC is higher than or equal to a first level from among the batteries, when weather information corresponds to weather information that requires safe driving of the vehicle.

In another example, the electronic device (e.g., the processor 130) may select, as the target battery, a battery in which an SOC is higher than or equal to a second level from among the batteries, when a tire pressure value of a vehicle including the electronic device is less than or equal to a threshold value.

In operation 1050, the electronic device may configure the power source based on the selected target battery (or batteries). For example, when multiple target batteries are selected from among the batteries, the electronic device may connect the selected target batteries by controlling corresponding circuitry associated with each of the target batteries. The corresponding circuitry may include (i) at least one of a switch (e.g., the switch 220 of FIG. 2) or a transformer (e.g., the transformer 320-2 of FIG. 3) connected in parallel to each target battery, and (ii) a switch (e.g., the switch 230 of FIG. 2 or the switch 330 of FIG. 3) connected in series to each target battery.

According to one or more embodiments, the electronic device may convert a voltage of power output from the configured power source into a level required by a load (e.g., the first load 830 or the second load 940).

The description provided with reference to FIGS. 1 through 8 may also apply to the operating method of the electronic device of FIG. 10.

The processors, power sources, converters, inverters, loads, batteries, circuitries, switches, and other apparatuses, devices, units, and components described herein, including descriptions with respect to respect to FIGS. 1-10, are implemented by or representative of hardware components. As described above, or in addition to the descriptions above, examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit (ALU), a digital signal processor (DSP), a microcomputer, a programmable logic controller, a field-programmable gate array (FPGA), a programmable logic array (PLU), a microprocessor, or any other device or combination of devices that is configured to respond to and execute instructions (e.g., code or coding) in a defined manner to achieve a desired result. In one example, a processor or computer includes, or is connected to, one or more memories storing the instructions or software that are executed by the processor or computer. Hardware components implemented by a processor or computer may execute the instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both, and thus while some references may be made to a singular processor or computer, such references also are intended to refer to multiple processors or computers. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. As described above, or in addition to the descriptions above, example hardware components may have any one or more different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing. Thus, references to a processor herein mean processing circuitry (e.g., circuitry that includes one or more processing element(s) circuits). One or more processors comprising processing circuitry also refers to each processor comprising processing circuitry, as well as some or all of the one or more processors comprising the same processing circuitry. In addition, processors(s) and controller(s), as a non-limiting example, do not mean human processing or human control, but rather, refer to hardware components as described herein, as non-limiting examples.

The methods illustrated in, and discussed with respect to, FIGS. 1-10 that perform the operations described in this application are performed by computing hardware, for example, by one or more processors or computers, implemented as described above implementing the instructions (e.g., computer or processor/processing device readable instructions) or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations. References to a processor, or one or more processors, as a non-limiting example, configured to perform two or more operations refers to a processor or two or more processors being configured to collectively perform all of the two or more operations, as well as a configuration with the two or more processors respectively performing any corresponding one of the two or more operations (e.g., with a respective one or more processors being configured to perform each of the two or more operations, or any respective combination of one or more processors being configured to perform any respective combination of the two or more operations). Likewise, a reference to a processor-implemented method is a reference to a method that is performed by one or more processors or other processing or computing hardware of a device or system.

The instructions or software to control computing hardware, for example, one or more processors or computers, to implement the hardware components and perform the methods as described above may be written as computer programs, code segments, or other executable instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media, and thus, not a signal per se. Thus, references herein to storage media mean storage media hardware, and does not mean to transitory media, nor a signal per se. As described above, or in addition to the descriptions above, examples of a non-transitory computer-readable storage medium include one or more of any of read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RW, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and/or any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above and all drawing disclosures, the scope of the disclosure is also inclusive of the claims and their equivalents, i.e., all variations within the scope of the claims and their equivalents are to be construed as being included in the disclosure.

What is claimed is:

1. A method of operating an electronic device, the method comprising:
determining state information of each of a plurality of batteries based on sensing data associated with each of the plurality of batteries;
obtaining information for configuring a power source to supply power;
selecting at least one target battery from among the batteries based on each of the determined state information and the obtained information; and
configuring the power source based on the selected target battery.

2. The method of claim 1, wherein the information for configuring the power source comprises any one or a combination of any two or more of a destination of a vehicle comprising the electronic device, driving environment information between a location of the vehicle and the destination, and state information of the vehicle.

3. The method of claim 1, wherein the selecting of the target battery comprises selecting the target battery based on a distance between a location of a vehicle comprising the electronic device and a destination of the vehicle, and a state of charge (SOC) of each of the batteries.

4. The method of claim 1, wherein
the obtaining of the information for configuring the power source comprises obtaining driving environment information between a location of a vehicle comprising the electronic device and a destination of the vehicle, and
the selecting of the target battery comprises selecting the target battery based on the obtained driving environment information, an SOC of each of the batteries, and a state of health (SOH) of each of the batteries.

5. The method of claim 1, wherein the selecting of the target battery comprises, selecting, as the target battery, a battery in a normal state in which a state of health (SOH) of the battery is greater than or equal to a first SOH value, when an operation mode of the electronic device is set to a life management mode for the batteries.

6. The method of claim 1, wherein the selecting of the target battery comprises selecting, as the target battery, a battery having a state of charge (SOC) greater than or equal to a first level, when weather information corresponds to weather information that requires safe driving of a vehicle comprising the electronic device.

7. The method of claim 1, wherein the selecting of the target battery comprises selecting, as the target battery, a battery having a state of charge (SOC) greater than or equal to a second level, when a tire pressure value of a vehicle comprising the electronic device is less than or equal to a threshold value.

8. The method of claim 1, further comprising:
converting a voltage of power output from the power source into a voltage required by a load.

9. The method of claim 1, wherein the configuring of the power source comprises, when multiple target batteries are selected, connecting the selected target batteries by controlling corresponding circuitry associated with each of the selected target batteries.

10. The method of claim 9, wherein the corresponding circuitry of each of the selected target batteries comprises:
either one or both of a switch and a transformer connected in parallel to each of the selected target batteries; and
a switch connected in series to each of the selected target batteries.

11. An electronic device comprising:
a plurality of batteries; and
one or more processors configured to:
determine state information of each of the batteries based on sensing data associated with each of the batteries;
obtain information for configuring a power source to supply power;
select at least one target battery from among the batteries based on each of the determined state information and the obtained information; and
configure the power source based on the selected target battery.

12. The electronic device of claim 11, wherein the information for configuring the power source comprises any one or a combination of any two or more of a destination of a vehicle comprising the electronic device, driving environment information between a location of the vehicle and the destination, and state information of the vehicle.

13. The electronic device of claim 11, wherein the one or more processors are further configured to select the target battery based on a distance between a location of a vehicle comprising the electronic device and a destination of the vehicle, and a state of charge (SOC) of each of the batteries.

14. The electronic device of claim 11, wherein the one or more processors are further configured to obtain driving environment information between a location of a vehicle comprising the electronic device and a destination of the vehicle, and select the target battery based on the obtained driving environment information, a state of charge (SOC) of each of the batteries, and a state of health (SOH) of each of the batteries.

15. The electronic device of claim 11, wherein the one or more processors are further configured to select, as the target battery, a battery in a normal state in which a state of health (SOH) is greater than or equal to a first SOH value, when an operation mode of the electronic device is set to a life management mode for the batteries.

16. The electronic device of claim 11, wherein the one or more processors are further configured to select, as the target battery, a battery having a state of charge (SOC) greater than or equal to a first level, when weather information requires safe driving of a vehicle comprising the electronic device.

17. The electronic device of claim 11, wherein the one or more processors are further configured to select, as the target battery, a battery having a state of charge (SOC) greater than or equal to a second level, when a tire pressure value of a vehicle comprising the electronic device is less than or equal to a threshold value.

18. The electronic device of claim 11, further comprising:
a converter configured to convert a voltage of power output from the power source into a voltage required by a load.

19. The electronic device of claim 11, wherein the one or more processors are further configured to, when multiple target batteries are selected, connect the selected target batteries by controlling corresponding circuitry of each of the selected target batteries.

20. The electronic device of claim 11, wherein the corresponding circuitry of each of the selected target batteries comprises:
either one or both of a switch and a transformer connected in parallel to each of the selected target batteries; and
a switch connected in series to each of the selected target batteries.
